(19) United States
(12) Patent Application Publication
(10) Pub. No.: US 2010/0275991 A1
(43) Pub. Date: Nov. 4, 2010

(54) Photovoltaic System, a Terminal Box Thereof and a Voltage Converting Device

(75) Inventor: Palvin Chee Leong Chan, San Francisco, CA (US)

Correspondence Address: BAKER & HOSTETLER LLP, WASHINGTON SQUARE, SUITE 1100, 1050 CONNECTICUT AVE. N.W., WASHINGTON, DC, 20036-5304, US

(73) Assignee: WUXI SUNTECH POWER CO., LTD., Wuxi (CN)

(21) Appl. No.: 12/768,637

(22) Filed: Apr. 27, 2010

(30) Foreign Application Priority Data
Apr. 29, 2009 (CN) 200910137271.0

(51) Int. Cl. H01L 31/00; H01R 13/46; H01R 13/52; H02M 7/42

(52) U.S. Cl. 136/256; 439/625; 439/271; 363/146

(57) ABSTRACT

A photovoltaic system, a terminal box and a voltage converting device thereof is provided. The terminal box and the voltage converting device have a connector plug or a connector socket, wherein said connector plug and connector socket are electrically connected by plugging. The photovoltaic system comprises a solar module, the terminal box and the voltage converting device, the terminal box and the voltage converting device being electrically connected by plugging the connector plug and connector socket, and the converting device being fixed to the solar module through a support member. With this photovoltaic system, the installation manner, which is free from conducting wires, is convenient, reliable and cost-effective.

### CROSS-REFERENCE TO RELATED APPLICATIONS

This application claims priority to foreign Patent Application CN 200910137271.0, filed on Apr. 29, 2009, the disclosure of which is incorporated herein by reference in its entirety.

### FIELD OF THE INVENTION

This invention relates to the photovoltaic power generating field, and particularly to a photovoltaic system, a terminal box and a voltage converting device thereof.

### BACKGROUND OF THE INVENTION

Solar energy, as a new energy source, is advantageously sustainable for exploitation compared with traditional fossil fuel. Today, with a pressingly gloomy international energy outlook, many countries are intensifying efforts to develop the solar energy industry and the application of solar energy is becoming more and more popular, such as solar panels for satellites in the aerospace field and solar water heater in daily life.

Currently, there are three major exploitation methods for solar energy, namely, photo-electrical conversion, photo-thermal conversion and photo-chemical conversion, among which photo-electrical conversion, i.e. converting solar energy into electrical energy, is the most popular. A solar cell is a typical photo-electrical converter. In practice, usually a photovoltaic system mainly consists of a solar module. And a complete photovoltaic power generating system mainly includes a solar module, a terminal box, a voltage converting device, such as an inverter, and other instruments. The basic principle is as follows: solar energy captured by the solar module is converted into electrical energy; the outputted electrical energy is leaded out through the terminal box; the outputted direct current is converted into alternate current by the voltage converting device; then the converted alternate current is incorporated in the public power network directly. Or the electrical energy may be stored in storage cells controlled by charging and discharging controllers. When charging, the storage cells receive the electrical energy outputted from the solar module; and when discharging, the storage cells output the electrical energy.

A photovoltaic system can be classified into two categories according to the application fields: an independent photovoltaic system and a grid-connected photovoltaic system. An independent photovoltaic system is mainly used in small scale systems that are independently powered and usually need storage cells, such as telecommunication systems, microwave relay stations, television signal transmitting stations and such areas that have no or scare power supply. A grid-connected photovoltaic system, which is operated together with a power grid, is mainly used for large and medium scale power generating systems and does not need any storage cells.

Whatever kind a photovoltaic system may be, it needs devices for outputting the electrical energy and converting direct current into alternate current. In other words, a terminal box for outputting the electrical energy and a voltage converting device, such as an inverter, are needed. Currently, when manufacturing a solar module, a terminal box is directly fixed to the solar module by solar module manufacturers in view of the small volume and light weight of the terminal box. When the solar module is to be installed in a photovoltaic system, the voltage converting device is fixed and installed. And the voltage converting device is connected with the terminal box through a power line. The installation figure is shown in the configuration figure of a photovoltaic system according to the prior art in FIG. 1. A terminal box 14 is directly bonded to the back surface of the solar module 11. An inverter 12 is fixed independently. And the terminal box 14 and the inverter 12 are connected by a conducting wire 13.

Such a wiring manner is not convenient for installation and is not reliable, since when the solar module and the inverter are independently fixed, it is not convenient to connect the wire of the inverter with the terminal box of the solar module. In addition, a photovoltaic system is usually used outdoors and, therefore, is easy to be affected by adverse environments, especially in a humid and hot environment. Thus, the wires can be easily destroyed, whereby the whole photovoltaic system will malfunction or its maintenance will become difficult. Moreover, for a large scale photovoltaic station, there will be many additional wires for connecting purpose, which affects the cost control of raw materials and manual installation.

### SUMMARY OF THE INVENTION

In view of the above, embodiments of the present invention advantageously provide a photovoltaic system, a terminal box and a voltage converting device thereof that are easy to install and more reliable.

Embodiments of the present invention provide a terminal box for a photovoltaic system, the terminal box including power line fixing terminals and a housing and having a first connector plug or a first connector socket electrically connected with the power line fixing terminal.

Embodiments of the present invention also provide a voltage converting device for a photovoltaic system, the voltage converting device having a second connector socket to be plugged with the first connector plug or a second connector plug to be plugged with the first connector socket;

Embodiments of the present invention also provide a photovoltaic system, comprising: a solar module, a terminal box and a voltage converting device, the terminal box being fixed to the solar module, and the voltage converting device being electrically connected with said terminal box, wherein the terminal box includes a first connector plug or a first connector socket; the voltage converting device includes a second connector socket to be adapted to the first connector plug or a second connector plug to be adapted to the first connector socket; the terminal box and the voltage converting device are electrically connected with each other through the plugging between the first connector plug and the second connector socket or the plugging between the first connector socket and the second connector plug; and the voltage converting device is fixed to the solar module through a support member.

The advantageous effects of this invention include, but are not limited to, the installation is easy and fast by using the plug connecting manner so that the installed photovoltaic system is integrally formed without conducting wires exposing in the environment, thereby improving the reliability of the photovoltaic system and saving costs for materials and manual installation.

### BRIEF DESCRIPTION OF THE DRAWINGS

FIG. 1 is a schematic drawing showing the connection configuration of the terminal box and an inverter of a photovoltaic system in the prior art.

FIG. 2 is a schematic drawing showing the configuration of a first embodiment of the terminal box for the photovoltaic system of this invention.

FIG. 3 is a schematic drawing showing the configuration of a first embodiment of the voltage inverting device for the photovoltaic system of this invention.

FIG. 4 is a schematic drawing showing the configuration of a first embodiment of the photovoltaic system of this invention.

FIG. 5 is a schematic drawing showing the configuration of the support member in FIG. 4.

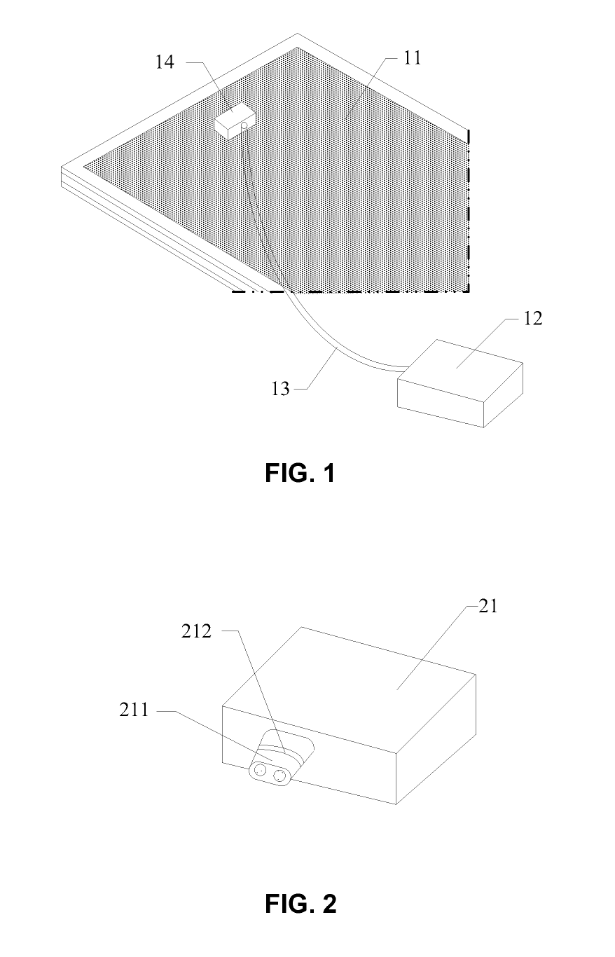

### DETAILED DESCRIPTION

The invention will now be described with reference to the drawing figures, in which like reference numerals refer to like parts throughout.

As shown in FIG. 2, which is the configuration schematic drawing of a first embodiment of the terminal box for the photovoltaic system of this invention, a connector plug 211 for connecting external electrical elements is provided on the outer wall of the terminal box 21. In order to make the connection more hermetical and free from the influence of the environment, a sealing ring groove 212 may be provided to the connector plug 211 and a sealing ring (not shown) may be fittingly provided to the sealing ring groove.

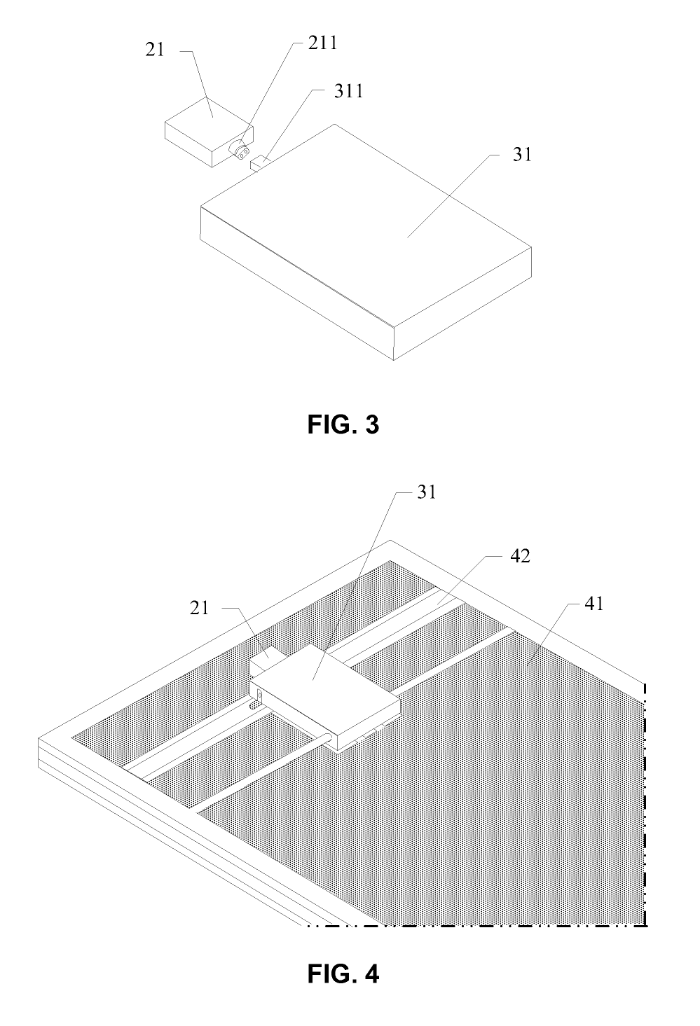

Correspondingly, as shown in FIG. 3, which is the configuration figure of a first embodiment of the voltage converting device for the photovoltaic system of this invention, the voltage converting device 31 is provided with a connector socket 311 to be adapted to the connector plug 211 of the terminal box 21. The connector plug 211 and the connector socket 311 only need to be plugged with each other in use so as to be electrically connected, thereby to facilitate the installation.

Of course, if a connector socket is provided to the terminal box 21 and a connector plug to be adapted to said connector socket is provided on the voltage converting device 31, the above object can also be realized. At this time, a sealing ring groove may be provided to the connector plug of the voltage converting device 31 and a sealing ring may be fittingly provided to the sealing ring groove.

The voltage converting device 31 in this embodiment may be an inverter having a DC-AC converting circuit electrically connected with the connector socket 311.

In another embodiment, in order to accommodate the inverters manufactured by different manufacturers to be adapt to the connector plug 211 of the terminal box 21, the connector socket 311 of the voltage converting device 31 may be provided on a circuit board or a concentrator, then the inverter is electrically connected with the circuit board or the concentrator. By doing so, easy installation can also be realized.

As the above described, compared with the prior art that a voltage converting device is connected with the terminal box of a solar module through wires, the plugging manner of this invention does not need wires for connecting, thereby to reduce the possibility of malfunctions, improve the reliability and facilitate installation as well.

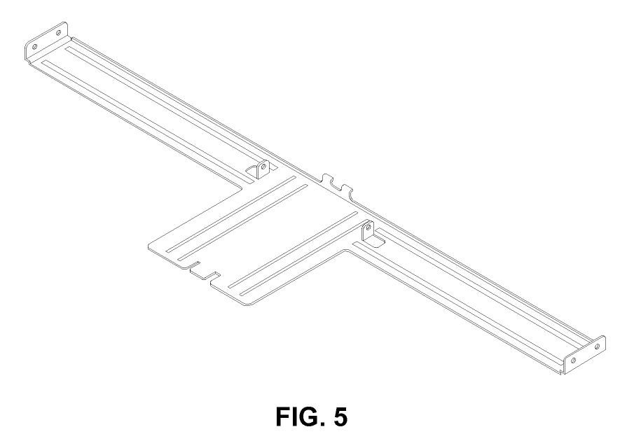

Referring to FIGS. 4 and 5, FIG. 4 shows the configuration of a first embodiment of the photovoltaic system of this invention. The photovoltaic system comprises a solar module 41, a terminal box 21 and a voltage converting device 31. The terminal box 21 is fixed to the back surface of the solar module 41 using, for example, adhesive. The voltage converting device 31 is fixed to the back surface of the solar module 41 via a support member 42 and is electrically connected with the terminal box 21 by plugging with each other. FIG. 5 shows the configuration of the support member 42 in FIG. 4. As shown in FIG. 5, the two ends of the support member 42 are fixing portions 421 fixed to the frame of the solar module 41 through, for example, bolts. The middle portion of the support member 42 is a catching portion 422 for positioning the voltage converting device 31.

In order to prevent the voltage converting device 31 from loosening, positioning plates 423 are provided to the both sides of the catching portion 422 and protruding plates 424 are provided to the bottom of the catching portion 422. Preferably, to strengthen the connection between the support member 42 and the solar module 41, a adhesive receiving groove 425 is provided to the side where the support member 42 is against the solar module 41. The adhesive (not shown), such as silicon, is provided inside the adhesive receiving groove 425.

When installing, the fixing portion 421 of the support member 42 is fixed to the frame of the solar module 41 with a bolt before the support member 42 is firmly bonded to the back surface of the solar module 41 with the silicon inside the adhesive receiving groove 425. Then, the voltage converting device 31 is placed and pushed upwards along the catching portion 422 of the support member 42. The connector plug of the terminal box 21 and the connector socket of the voltage converting device 31, or the connector socket of the terminal box 21 and the connector plug of the voltage converting device 31 are plugged with each other to allow electrical connection. Then, the voltage converting device 31 and the positioning plates 423 on the 422 of the support member 42 are fixed by bolts.

Similarly, the voltage converting device 31 of this invention may be an inverter having a DC-AC converting circuit that is electrically connected with the connector socket 311.

To make the connection more hermetical and avoid the influence from the environment, a sealing ring groove provided with a sealing ring therein may be provided to the connector plug of the terminal box 21 or the connector plug of the voltage converting device 31.

As the above described, the terminal box and the voltage converting device of the photovoltaic system in this invention are coupled with each other by directly plugging the plug and the socket without any connecting wires. Therefore, the installation manner is convenient, reliable, adaptive to different environments and cost-effective.

It should be noted that, it's not necessary for the voltage converting device to correspond to the solar module one by one in the present invention, as known for the skilled person in the art, maybe one voltage converting device can correspond to a plurality of solar modules, that is, not every solar module of the photovoltaic system has the terminal box and the voltage converting device and its support member as described in the present invention. For example, when using one voltage converting device to work for a plurality of solar modules, it's feasible that only one solar module is installed, on its back, with the terminal box, the voltage converting device and its support member as described in the present invention, and the other solar modules are installed with the traditional terminal box on their back, respectively.

The many features and advantages of the invention are apparent from the detailed specification, and, thus, it is intended by the appended claims to cover all such features and advantages of the invention which fall within the true spirit and scope of the invention. Further, since numerous modifications and variations will readily occur to those skilled in the art, it is not desired to limit the invention to the exact construction and operation illustrated and described, and, accordingly, all suitable modifications and equivalents may be resorted to that fall within the scope of the invention.

What is claimed is:

1. A terminal box for a photovoltaic system, comprising:
a power line fixing terminal;
a housing; and
a first connector plug or a first connector socket electrically connected to the power line fixing terminal.

2. The terminal box according to claim 1, wherein the first connector plug includes a sealing ring groove, and a sealing ring is fittingly provided in the sealing ring groove.

3. A voltage converting device for a photovoltaic system, comprising a second connector socket or a second connector plug pluggable with the first connector plug or the first connector socket of the terminal box according to claim 1.

4. The voltage converting device according to claim 3, wherein the voltage converting device is an inverter having a DC-AC converting circuit that is electrically connected to the second connector socket or the second connector plug.

5. The voltage converting device according to claim 3, wherein the second connector plug includes a sealing ring groove, and a sealing ring is fittingly provided in the sealing ring groove.

6. A photovoltaic system, comprising:
a solar module;
a terminal box, fixed to the solar module, including a first connector plug or a first connector socket; and
a voltage converting device, fixed to the solar module through a support member, including a second connector socket that cooperates with the first connector plug or a second connector plug that cooperates with the first connector socket,
wherein the terminal box and the voltage converting device are electrically connected to each other by coupling the first connector plug and the second connector socket or by coupling the first connector socket and the second connector plug.

7. The photovoltaic system according to claim 6, wherein the voltage converting device is an inverter having a DC-AC converting circuit that is electrically connected to the first connector socket or the first connector plug.

8. The photovoltaic system according to claim 6, wherein the first or second connector plug includes a sealing ring groove, and a sealing ring is fittingly provided in the sealing ring groove.

9. The photovoltaic system according to claim 6, wherein the support member comprises:
fixing portions, provided at both ends of the support member, for supporting the solar module; and
a catching portion, provided at the middle portion of the support member, for positioning the voltage converting device.

10. The photovoltaic system according to claim 9, wherein an adhesive receiving groove is provided on the side of the support member that is against the solar module, and an adhesive is provided inside the adhesive receiving groove for fixing the support member and the solar module together.

11. The photovoltaic system according to claim 9, wherein positioning plates are provided on the both sides of the catching portion, and protruding plates are provided on the bottom of the catching portion, such that the positioning plates and protruding plates support the voltage converting device.
